(19) United States
(12) Patent Application Publication
(10) Pub. No.: US 2009/0314643 A1
(43) Pub. Date: Dec. 24, 2009

(54) Electrophoresis Cassette and Method for Producing the Same

(75) Inventors: Koji Sakairi, Kazo-shi (JP); Chie Hayashida, Funabashi-shi (JP); Ichiji Namatame, Tsukuba-shi (JP); Kenji Yokoyama, Tsukuba-shi (JP); Atsunori Hiratsuka, Yokohama-shi (JP); Kisho Shiseki, Tokyo (JP)

Correspondence Address: STAAS & HALSEY LLP, SUITE 700, 1201 NEW YORK AVENUE, N.W., WASHINGTON, DC, 20005, US

(73) Assignees: Toppan Printing Co., Ltd., Tokyo (JP); National Institute of Advanve Industrial Scienc and Technology, Tokyo (JP); Sharp Kabushiki Kaisha, Osaka (JP); Katayanagi Institute, Tokyo (JP)

(21) Appl. No.: 12/224,337

(22) PCT Filed: Feb. 28, 2007
(86) PCT No.: PCT/JP2007/053796

§ 371 Date: Mar. 24, 2009

(30) Foreign Application Priority Data
Feb. 28, 2006 (JP) 2006-052543
Feb. 28, 2006 (JP) 2006-052544

(51) Int. Cl. C25B 9/00; C23C 16/513

(52) U.S. Cl. 204/600; 427/579

(57) ABSTRACT

The object of the present invention is to inject smoothly a precursor to be a support and make an excellent support in which a boundary between a separation gel and a concentration gel after the injection is not ill-defined in the cassette which is made by combining two plates made of a synthetic resin, and in order to achieve the object, the present invention provides an electrophoresis cassette made by combining plates made of a synthetic resin which has a cavity for forming a support, wherein the surface of the plate which contacts with the support is covered with a SiOx film, and the SiOx film has a contact angle to water of 30° or less, and preferably 10° or less.

### TECHNICAL FIELD

The present invention relates to an electrophoresis cassette which is used in chemical analysis, and the like. In particular, the present invention relates to an electrophoresis cassette wherein injection of a precursor liquid to be a support and formation of a support are performed without any problems.

Priority is claimed on Japanese Patent Applications No. 2006-052543 and No. 2006-052544, filed Feb. 28, 2006, the content of which is incorporated herein by reference.

### BACKGROUND ART

Examples of an electrophoresis cassette (below, it may be abbreviated as only “cassette”) include a one-dimensional cassette using one kind of medium which is formed by facing and combining two substrates 1 and 2, as shown in FIG. 6. In the one-dimensional cassette, a recessed portion 3 is formed in one substrate 1. A cavity for forming a support, such as polyacryl amide gel, is formed by the recessed portion 3.

This type of a cassette has been generally formed by a glass plate. However, recently, a plate made of a synthetic resin, such as a styrene resin, and an acrylic resin, is gradually used (Patent Document 1).

The cassette comprising plates made of a synthetic resin has advantages, for example, the cassette is commercially manufactured with ease by an injection forming method, and this is not readily broken.

However, the surface of the plate made of a synthetic resin is hydrophobic and has lower hydrophilicity compared to the plate made of glass. Therefore, when a precursor liquid to be a support, such as liquid acrylic amide before hardening, is injected into the cassette made of a synthetic resin, compatibility between the precursor to be a support and the surface of the plate is inferior. Due to this, it is impossible to inject smoothly the precursor to be a support into the cassette. Since the injection is sometimes not uniform, there is a problem in that a boundary between a separation gel and a concentration gel after injection is ill-defined.

Patent Document No. 1: Japanese Unexamined Patent Application, First Publication No. H10-132785

### DISCLOSURE OF THE INVENTION

### Problems to be Solved

The problem to be solved by the present invention is to inject smoothly a precursor to be a support and make an excellent support in which a boundary between a separation gel and a concentration gel after the injection is not ill-defined in the cassette which is made by combining two plates made of a synthetic resin.

### Means for Solving the Problem

In order to solve the problems, the present invention provides an electrophoresis cassette made by combining plates made of a synthetic resin which has a cavity for forming a support, wherein the surface of the plate which contacts with the support is covered with a SiOx film, and the SiOx film has a contact angle to water of 30° or less.

In the electrophoresis cassette, it is preferable that a plastic film be provided between the surface of the support and the SiOx film.

In the electrophoresis cassette, it is preferable that an anchor treatment layer be provided between the surface of the support and the SiOx film.

In the electrophoresis cassette, it is preferable that a plastic film and an anchor treatment layer be provided between the surface of the support and the SiOx film, the plastic film be provided on the surface of the support, and the anchor treatment layer be provided between the plastic film and the SiOx film.

In the electrophoresis cassette, it is also preferable that the anchor treatment layer and the SiOx film be successively formed.

In addition, in order to solve the problems, the present invention provides a production method for an electrophoresis cassette which is made by combining plates made of a synthetic resin in which an anchor treatment layer and a SiOx film are formed by a plasma chemical vapor deposition method directly on the plate or via a plastic film on the plate, wherein the formation of the anchor treatment layer and the SiOx film by a plasma chemical vapor deposition method is carried out successively using the same raw material gas.

### EFFECTS OF THE PRESENT INVENTION

According to the present invention, compatibility, that is, wettability, between the precursor liquid to be a support and the outermost surface of the plate is improved. Thereby, it is possible to inject smoothly the precursor liquid to be a support. Due to this, it is possible to form a support in which a boundary between a separation gel and a concentration gel is not ill-defined.

In addition, when a plastic film is adhered on the plate, and a SiOx film is formed on the plastic film, it is possible to prevent damage of gel which is caused by damage of the cassette, and the like, in removing the gel after electrophoresis from the cassette.

The SiOx film has relative low oxygen permeability. Therefore, when the precursor liquid to be a support such as acrylamide is polymerized, oxygen migration from the plates made of a synthetic resin is prevented, and polymerization of the precursor liquid to be a support is not blocked.

In the electrophoresis cassette having the anchor treatment layer between the plate and the SiOx film, adhesion between the plate and the SiOx film is improved. Thereby, peeling of the SiOx film from the plate is prevented. The electrophoresis cassette can be used for a long period of time.

When the anchor treatment layer and the SiOx film are formed successively, adhesion between them is improved. As a result, connecting between the plate and the SiOx film can be enhanced.

When the plastic film is adhered on the surface of the plate, and the anchor treatment layer and the SiOx film are formed on the plastic film, it is possible to prevent damage of gel which is caused by damage of the cassette, and the like, in removing the gel after electrophoresis from the cassette.

### BRIEF DESCRIPTION OF THE DRAWINGS

FIG. 1 is an outline sectional view showing an important section of a first embodiment of a plate which constitutes the cassette of the present invention.

FIG. 2 is an outline sectional view showing an important section of a second embodiment of a plate which constitutes the cassette of the present invention.

FIG. 3 is an outline sectional view showing an important section of a third embodiment of a plate which constitutes the cassette of the present invention.

FIG. 4 is an outline sectional view showing an important section of a fourth embodiment of a plate which constitutes the cassette of the present invention.

FIG. 5A is an outline sectional view showing a two-dimensional electrophoresis cassette of the present invention.

FIG. 5B is an outline plan view showing a two-dimensional electrophoresis cassette of the present invention.

FIG. 6 is a perspective view showing a one-dimensional electrophoresis cassette of the present invention.

DESCRIPTION OF REFERENCES

| | | | |
|---|---|---|---|
| 1, 2, 11: | plate | 3: | recessed portion |
| 12: | anchor treatment layer | 13: | SiOx film |
| 14: | plastic film | 24: | support containing portion |
| 28a: | first buffer vessel | 28b: | second buffer vessel |

### BEST MODE FOR CARRYING OUT THE INVENTION

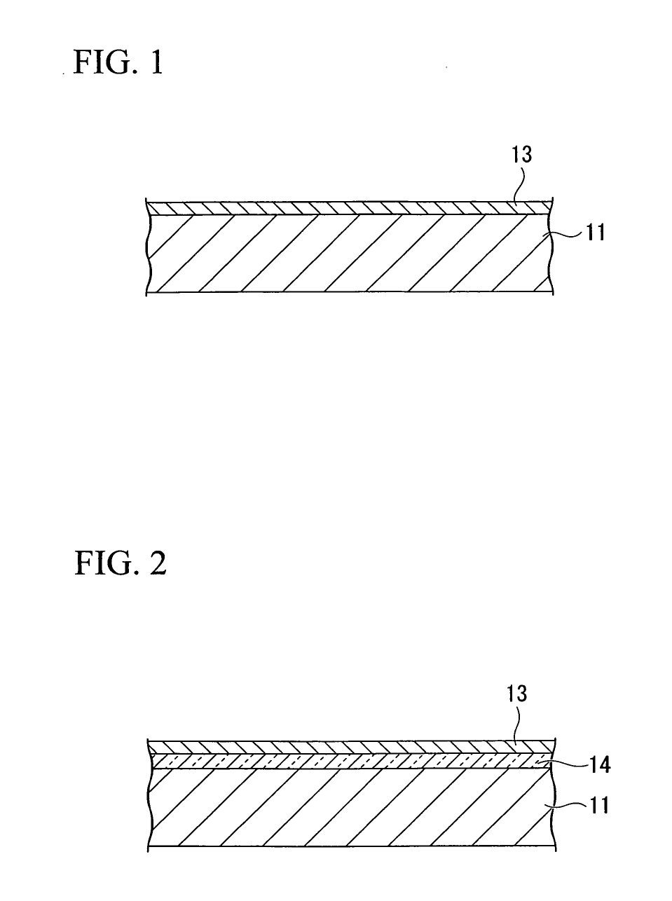

FIG. 1 shows an important section of a first embodiment of a cassette of the present invention. The reference number 11 denotes a plate constituting the cassette.

The plate 11 is made of a synthetic resin, such as a styrene resin, a styrene-acrylonitrile copolymer, an acrylic resin, a polyester resin, a cellulose resin, a vinyl chloride resin. The plate 11 is made by an injection forming method, and the like.

A SiOx film 13 is formed on the surface of the plate 11 with which a support contacts. The SiOx film 13 is a thin film which has a thickness of 30 to 100 nm and is made of silicon oxide in which x is 1 to 2. The contact angle with water of the SiOx film 13 is 30° or less, and preferably 10° or less. When the contact angle exceeds 30°, hydrophilicity of the surface of the plate 11 is insufficient, and smooth injection of a precursor liquid to be a support is impossible.

The SiOx film 13 is formed directly on the surface of the plate 11 by a thin film formation method, such as a deposition method, a sputtering method, a CVD method, and a plasma CVD method. Among these methods, a plasma CVD method in which a mixture gas containing siloxane such as hexamethyl siloxane and oxygen at a flow rate of 10:100 to 5:100 is used as a raw material gas is preferable.

The SiOx film having the contact angle of 30° or less can be produced by such a thin film formation method by controlling conditions such as the mixing ratio between siloxane and oxygen, which are the raw materials.

For example, when the SiOx film having such a contact angle is produced by a plasma CVD method, the conditions are selected from; plate temperature: −30 to 50° C., pressure: 0.01 to 300 Pa, plasma output: 50 to 800 W, disiloxane flow rate: 5 to 50 sccm, oxygen flow rate: 50 to 200 sccm, and time: 10 to 600 seconds.

In the SiOx film 13, the carbon content in atomic percentage is preferably 6% or less, and more preferably 4.8%. The lower the carbon percentage is, the higher the compatibility is. In other words, when the carbon percentage is lower, the contact angle can be smaller. That is, the lowest carbon content is most preferably 0%. It is possible to make the carbon content 6% or less by controlling conditions in a thin film formation method, such as a plasma CVD method.

In the cassette of the present invention, the surface of the plate 11 has high compatibility by forming the SiOx film 13 on the surface of the plate 11. Thereby, when the precursor liquid to be a support is injected into the cavity, the precursor liquid is spread on the surface of the plate 11, and the injection is smoothly carried out.

In addition, the boundary between a separation gel and a concentration gel after injection is not ill-defined, and the boundary is uniform

Furthermore, the SiOx film 13 has oxygen barrier properties. Therefore, oxygen migration from the plate 11 is prevented. Thereby, it is possible to prevent inhibition of polymerization of the precursor liquid, such as acrylamide, due to oxygen.

FIG. 2 shows an important section of a second embodiment of a cassette of the present invention. Moreover, the components shown in FIG. 2 which are the same as the components of the first embodiment have the same reference numerals as in the first embodiment. Thereby, an explanation for those same components is omitted in this embodiment.

In this embodiment, a plastic film 14 is formed on the surface of the plate 11 which contacts the support. In addition, the SiOx film 13 is formed on the surface of the plastic film 14.

Examples of the plastic film 14 include a film having a thickness of 10 to 300 μm made of polystyrene, polyethylene terephthalate, polymethyl methacrylate, cyclic olefin, polyethylene, or cellulose acetate. The plastic film 14 is adhered to the plate 11 using an adhesive or by melting.

The SiOx film 13 can be formed on the surface of the plastic film 14 by the thin film formation methods which are explained above. Among these, a plasma CVD method is preferable.

When the plastic film 14 is adhered to the surface of the plate 11, and the SiOx film 13 is further formed on the surface of the plastic film 14, effects, in that when a gel after finishing electrophoresis is removed from the cassette, damage of the gel due to damage of the cassette and the like can be prevented, are obtained in addition to the effects which are obtained in the first embodiment.

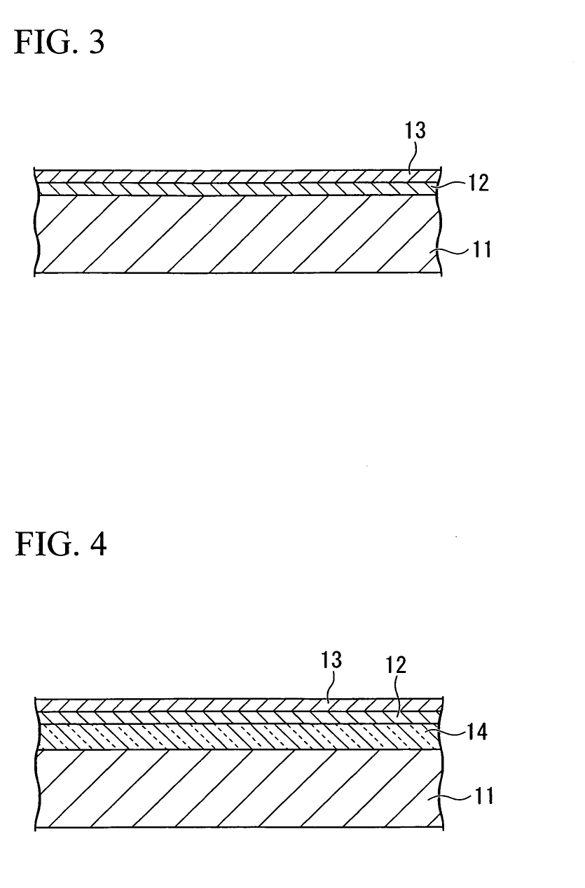

FIG. 3 shows an important section of a third embodiment of the cassette of the present invention. Moreover, the components shown in FIG. 3 which are the same as the components of the first embodiment have the same reference numerals as in the first embodiment. Thereby, an explanation for those same components is omitted in this embodiment.

In this embodiment, an anchor treatment layer 12 is formed on the surface of the plate 11 which contacts the support. The SiOx film 13 is further formed on the anchor treatment layer 12. The anchor treatment layer 12 improves adhesion force of the SiOx film 13 to the plate 11. The anchor treatment layer 12 is a polymer film comprising disiloxane such as hexamethyl disiloxane having a thickness of 20 to 300 nm.

The anchor treatment layer 12 can be produced by various methods. Examples of the production method for the anchor treatment layer 12 include a coating method such as a spin coating method and an ink jet method, and a method in which the plate 11 is dipped into an anchor treatment solution. In addition, the anchor treatment layer 12 may be produced by extruding an anchor treatment agent together with a resin contributing the plate.

A thin film production method in vacuum conditions is preferably used to produce the anchor treatment layer 12. When the thin film production method in vacuum conditions is used, a uniform anchor treatment layer can be produced without being affected by the shape of the plate 11. Examples of the thin film production method include a CVD method, and a plasma CVD method. Among these thin film production methods, a plasma CVD method using siloxane, such as hexamethyl disiloxane, as material gas is the most preferable.

When the anchor treatment layer 12 is produced by a plasma CVD method, for example, the production condition is selected from the plate temperature of −30 to 50° C., the pressure of 0.01 to 300 Pa, the plasma output of 50 to 800 W, the flow rate of disiloxane of 3 to 50 sccm, and the treatment time of 10 to 600 seconds.

The SiOx film 13 can be produced similarly in the first embodiment.

Moreover, the content of carbon in an atomic percentage of the SiOx film 13 in the third embodiment is preferably 10% or less, and more preferably 5% or less. When the content of carbon is smaller, the obtained SiOx film 13 has higher hydrophilicity. As a result, the contact angle to water can be decreased. In other words, the most preferable lower limit in the content of carbon is 0%. The content of carbon can be adjusted to 10% or less by controlling production conditions in a thin film production method such as a plasma CVD method.

When the anchor treatment layer 12 and the SiOx film 13 are produced by a plasma method, it is preferable to produce these layers successively. Specifically, the anchor treatment layer 12 is formed on the plate 11 by supplying disiloxane, such as hexamethyl disiloxane, as raw material into a chamber of a plasma CVD apparatus, and plasma-polymerizing it. Then, the SiOx film 13 is produced on the anchor treatment layer 12 successively by supplying disiloxane, such as hexamethyl disiloxane, and oxygen as raw materials into the chamber while retaining the conditions of the chamber.

That is, the anchor treatment layer 12 is formed by adjusting the amount of oxygen to 0 or extremely small. The SiOx film 13 is formed by increasing the flow ratio of oxygen compared to the anchor treatment layer 12. The SiOx film 13 is formed immediately after the anchor treatment layer 12.

When the successive film production method is used, productivity of the cassette is also improved, in addition that the adhesion force between the anchor treatment layer 12 and the SiOx film 13 is improved.

In the cassette, when the SiOx film 13 is formed on the surface of the plate 11, the surface of the plate 11 achieves high hydrophilicity. When the precursor liquid to be a support is loaded into the cavity, the precursor is easily spread over the surface of the plate 11, and injection of the precursor is smoothly carried out. In addition, the boundary between a separation gel and a concentration gel after injection is not ill-defined, and a uniform boundary is obtained.

In addition, since the SiOx film 13 has oxygen barrier properties, migration of oxygen from the plate 11 is prevented. Therefore, it is possible to prevent the polymerization inhibition of the precursor, such as acrylamide, due to oxygen.

Furthermore, when the anchor treatment layer 12 is formed, the adhesion between the SiOx film 13 and the plate 11 is improved. Therefore, even when the cassette is used for a long time, the SiOx film 13 does not peel, and the effects obtained by the SiOx film 13 can be maintained.

FIG. 4 shows an important section of a fourth embodiment of the cassette according to the present invention. Moreover, the components shown in FIG. 4 which are the same as the components of the first embodiment have the same reference numerals as in the first embodiment. Thereby, an explanation for those same components is omitted in this embodiment.

In the fourth embodiment, the plastic film is adhered to the surface of the plate 11 which contacts the support, and the anchor treatment layer 12 and the SiOx film 13 are formed on the surface of the plastic film 14.

The plastic film 14 can be produced using the same material constituting the plastic film 14 by the same production method used in the second embodiment.

When the plastic film 14 is adhered on the surface of the plate 11, and the anchor treatment layer 12 and the SiOx film 13 are formed on the surface of the plastic film 14, damage of the gel due to damage of the cassette and the like can be prevented in removing the gel after electrophoresis from the cassette, in addition to the effects which are obtained in the previous embodiments.

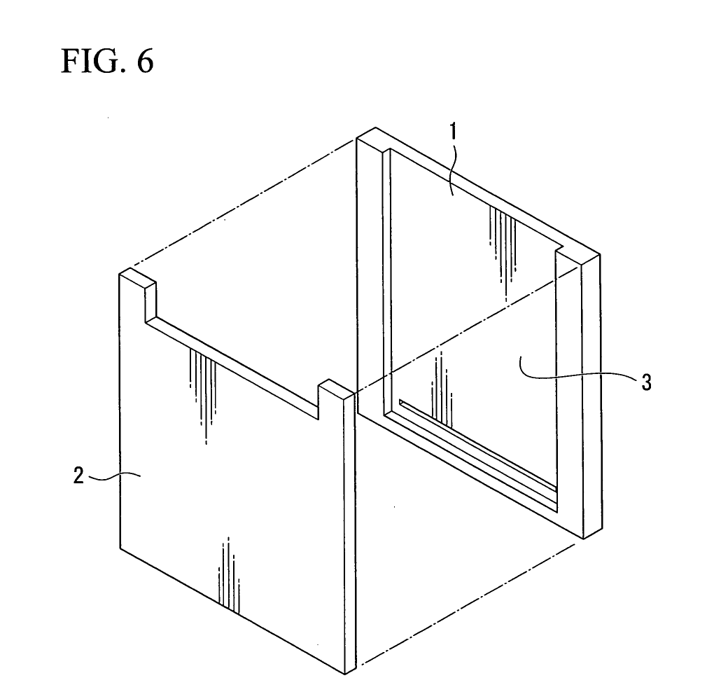

Examples of the cassette of the present invention include the one-dimensional cassette comprising the plates provided with the SiOx film 13, and the plastic film and/or the anchor treatment layer if necessary shown in FIG. 6. In a one-dimensional cassette, a gel is loaded in a recessed portion 3 in the plate 1. Therefore, the plate constituting at least the recessed portion 3 has the characteristic layer structure.

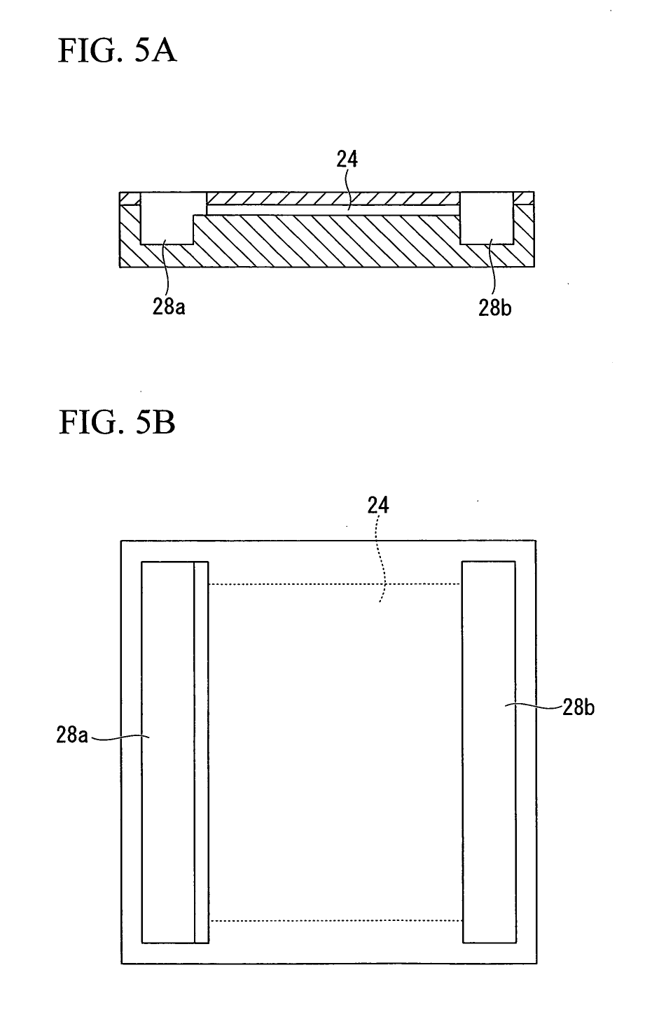

The cassette of the present invention also includes a two-dimensional cassette of which the cross-sectional view is shown by FIG. 5A, and the planar view is shown by FIG. 5B. The two-dimensional cassettes shown in FIG. 5 comprises a first buffer vessel 28a and a second buffer vessel 28b, and a support container portion 24 between the first and second buffer vessels 28a and 28b. A gel is loaded with the support container portion 24. Therefore, the plate constituting at least the support container portion 24 has the characteristic layer structure.

### EXAMPLES

### Example 1

Plates in pairs constituting the cassette were produced by injection molding a styrene resin. The plates were put into a chamber of a plasma CVD device. Then, the pressure inside the chamber was reduced to 1.5×10⁻³ Pa. After reducing the pressure, hexamethyldisiloxane (HMDS) and oxygen were simultaneously introduced into the chamber. The plasma output, the plate temperature, and treatment time were adjusted to 300 W, 20° C., and 120 seconds, respectively. Thereby, the SiOx film having the thickness of about 70 nm was produced on the plates.

During production of the SiOs film, the flow rate of HMDS and oxygen introduced into the chamber were varied shown in Table 1. The contact angle to water of the obtained SiOx film was measured, and the results are shown compared with the flow rate of HMDS and oxygen.

TABLE 1

| | Flow rate of HMDS | Flow rate of oxygen | Contact angle |
|---|---|---|---|
| Sample No. | (sccm) | (sccm) | (°) |
| 1 | 5 | 100 | 6.9 |
| 2 | 8 | 120 | 14.7 |
| 3 | 9 | 108 | 34.5 |
| 4 | 10 | 100 | 46.6 |

It is clear from Table 1 that the contact angle to water of the obtained SiOx film can be changed and controlled by changing and controlling the flow rate of HMDS and oxygen introduced into the chamber.

After that, the cassette was produced using the plates provided with the SiOx film. An acrylamide solution was poured in the cavity. The injection conditions of the acrylamide solution and forming conditions of the acrylamide gel were observed.

The acrylamide solution for a separation gel was prepared as follows.
30% acrylamide solution

(acrylamide 28%, N,N′-methylene bisacrylamide 2%): 2.15 ml
distilled water: 1.55 ml
tris-hydrochloric acid buffer solution (pH 8.8, 1.5M): 1.25 ml
ammonium persulfate: 50 μl
N,N,N′,N′-tetramethylethylene diamine: 5 μl

The acrylamide solution comprising the compositions was injected in the cavity of the cassette and distilled water was superimposed thereon to form a separation gel. After obtaining the separation gel, the superimposed distilled water was removed. Then, an acrylamide solution for a concentration gel having the following compositions was injected and distilled water was further superimposed thereon to form a concentration gel.
30% acrylamide solution

(acrylamide 28%, N,N′-methylene bisacrylamide 2%): 0.65 ml
distilled water: 3.05 ml
tris-hydrochloric acid buffer solution (pH 8.8, 1.5M): 1.25 ml
ammonium persulfate: 50 μl
N,N,N′,N′-tetramethylethylene diamine: 10 μl

Loading properties (conditions when injecting) of the two acrylamide solutions into the cassette and gel formation properties (forming conditions of gel) after injection were observed. The results are shown in Tables 2 and 3.

Moreover, loading properties and gel formation properties were judged based on the characters of the cassette comprising glass plates. Specifically, when the cassette has the same level of loading properties and gel forming properties as those of the glass plate, it was evaluated as excellent. When the cassette had the approximate same level of loading properties and gel forming properties as those of the glass plate, it was evaluated as good. When the cassette had slightly inferior properties, it was evaluated as slightly inferior. When the cassette had considerable inferior properties, it was evaluated as bad.

In addition, a cassette (Sample No. 5) comprising plates provided with a water-repellent film produced by a plasma CVD method using only HMDS without oxygen and a cassette (Sample No. 6) comprising glass plates were also evaluated for comparison. The results are also shown in Tables 2 and 3.

TABLE 2

| | | Loading properties | |
|---|---|---|---|
| | | (injection of the | |
| Sample | Contact angle | solution into the | |
| No. | (°) | cassette) | Others |
| 1 | 6.9 | Excellent | The gel solution can be injected smoothly |
| | | | similar to the cassette comprising glass plates |
| 2 | 14.7 | Good | Basically, the gel solution was injected |
| | | | smoothly |
| 3 | 34.5 | Slightly inferior | The gel solution was slightly shed on the plate |
| | | | and injected slightly nonuniformly. |
| 4 | 46.6 | Slightly inferior | The gel solution was slightly shed on the plate |
| | | | and injected slightly nonuniformly. |
| 5 | 98 | Poor | The gel solution was shed by the plate and was |
| | | | injected slightly nonuniformly. |
| 6 | 12 | Excellent | — |

TABLE 3

| Sample | Contact angle | Gel forming | |
|---|---|---|---|
| No. | (°) | properties | Others |
| 1 | 6.9 | Excellent | The boundary between the separation gel and |
| | | | the concentration was linear, and the gel |
| | | | boundary was defined. |
| 2 | 14.7 | Good | The boundary between the separation gel and |
| | | | the concentration was basically linear, and the |
| | | | gel boundary was defined. |
| 3 | 34.5 | Slightly inferior | Slightly ill-defined boundary between the |
| | | | separation gel and the concentration was |
| | | | confirmed. |
| 4 | 46.6 | Slightly inferior | Slightly ill-defined boundary between the |
| | | | separation gel and the concentration was |
| | | | confirmed. |
| 5 | 98 | Poor | Large distortion was confirmed at the boundary |
| | | | between the separation gel and the |
| | | | concentration. |
| 6 | 12 | Excellent | — |

It was confirmed from Tables 2 and 3 that the cassette comprising the synthetic plates provided with the SiOx film having a contact angle of 30° or less had the same level of loading properties and gel formation properties as those of the cassette comprising glass plates.

### Example 2

A cassette was produced and evaluated in a manner identical to that of Example 1, except that a plastic film comprising polyethylene terephthalate was adhered with an epoxy adhesive on the surface of a styrene resin plate obtained by an injection molding method, and the SiOx film was formed on the plastic film. The same evaluation results as those shown in Tables 2 and 3 were obtained.

### Example 3

Plates in pairs constituting the cassette were produced by injection molding a styrene resin. The plates were put into a chamber of a plasma CVD device. Then, the pressure inside the chamber was reduced to 1.5×10⁻³ Pa. After reducing the pressure, HMDS was introduced at a flow rate of 20 sccm into the chamber. The plasma output, the plate temperature, and treatment time were adjusted to 600 W, 20° C., and 60 seconds, respectively, to perform plasma polymerization. Thereby, the anchor treatment layer having the thickness of about 110 nm was produced on the plates.

The plates comprising the anchor treatment layer produced in these processes were left undisturbed in the chamber of the plasma CVD device, and HMDS and oxygen were simultaneously introduced into the chamber while maintaining the pressure inside the chamber to 1.5×10⁻³ Pa. The plasma output, the plate temperature, and treatment time were adjusted to 300 W, 20° C., and 120 seconds, respectively. Thereby, the SiOx film having the thickness of 70 nm was produced on the anchor treatment layer by plasma CVD.

During production of the SiOx film, the flow rate of HMDS and oxygen introduced into the chamber were varied as shown in Table 4. The contact angle to water of the obtained SiOx film was measured, and the results are shown compared with the flow rate of HMDS and oxygen.

TABLE 4

| | Flow rate of HMDS | Flow rate of oxygen | Contact angle |
|---|---|---|---|
| Sample No. | (sccm) | (sccm) | (°) |
| 7 | 5 | 100 | 6.9 |
| 8 | 8 | 120 | 14.7 |
| 9 | 9 | 108 | 34.5 |
| 10 | 10 | 100 | 46.6 |

It is clear from Table 4 that the contact angle to water of the obtained SiOx film can be changed and controlled by changing and controlling the flow rate of HMDS and oxygen introduced into the chamber.

After that, the cassette was produced using the plates provided with the anchor treatment layer and the SiOx film. An acrylamide solution, which was used as the separation gel and the concentration gel in Example 1, was poured in the cavity. The injection conditions of the acrylamide solution and forming conditions of the acrylamide gel were observed. The results are shown in Tables 5 and 6.

The loading properties of the solution and the gel formation properties were evaluated in a manner identical to that in Examples.

In addition, a cassette (Sample No. 11) comprising plates provided with a water repellent film produced by a plasma CVD method using only HMDS without oxygen and a cassette (Sample No. 12) comprising glass plates were also evaluated for comparison. The results are also shown in Tables 5 and 6.

TABLE 5

| | | Loading properties | |
|---|---|---|---|
| | | (injection of the | |
| Sample | Contact angle | solution into the | |
| No. | (°) | cassette) | Others |
| 7 | 6.9 | Excellent | The gel solution can be injected smoothly |
| | | | similar to the cassette comprising glass plates |
| 8 | 14.7 | Good | Basically, the gel solution was injected |
| | | | smoothly |
| 9 | 34.5 | Slightly inferior | The gel solution was shed slightly by the plate |
| | | | and was injected slightly nonuniformly. |
| 10 | 46.6 | Slightly inferior | The gel solution was shed slightly by the plate |
| | | | and was injected slightly nonuniformly. |
| 11 | 98 | Poor | The gel solution was shed by the plate and |
| | | | uniform injection was impossible. |
| 12 | 12 | Excellent | — |

TABLE 6

| Sample | Contact angle | Gel forming | |
|---|---|---|---|
| No. | (°) | properties | Others |
| 7 | 6.9 | Excellent | The boundary between the separation gel and |
| | | | the concentration was linear, and the gel |
| | | | boundary was defined. |
| 8 | 14.7 | Good | The boundary between the separation gel and |
| | | | the concentration was almost linear, and the gel |
| | | | boundary was defined. |
| 9 | 34.5 | Slightly inferior | Slightly ill-defined boundary between the |
| | | | separation gel and the concentration was |
| | | | confirmed. |
| 10 | 46.6 | Slightly inferior | Slightly ill-defined boundary between the |
| | | | separation gel and the concentration was |
| | | | confirmed. |
| 11 | 98 | Poor | Large distortion was confirmed at the boundary |
| | | | between the separation gel and the |
| | | | concentration. |
| 12 | 12 | Excellent | — |

It was confirmed from Tables 5 and 6 that the cassette comprising the synthetic plates provided with the SiOx film having a contact angle of 30° or less had the same level of loading properties and gel formation properties as those of the cassette comprising glass plates.

### Example 4

A cassette was produced and evaluated in a manner identical to that of Example 3, except that a plastic film comprising polyethylene terephthalate was adhered with an epoxy adhesive on the surface of a styrene resin plates obtained by an injection molding method, and the anchor treatment layer and the SiOx film were formed on the plastic film. The same evaluation results as those shown in Tables 5 and 6 were obtained.

### INDUSTRIAL APPLICABILITY

According to the present invention, compatibility, that is, wettability, between the precursor liquid to be a support and the outermost surface of the plate is improved. Thereby, it is possible to inject smoothly the precursor liquid to be a support. Due to this, it is possible to form a support in which a boundary between a separation gel and a concentration gel after the injection is not ill-defined.

In addition, when a plastic film is adhered on the plate, and a SiOx film is formed on the plastic film, it is possible to prevent damage of gel which is caused by damage of the cassette and the like in removing the gel after electrophoresis from the cassette.

1. An electrophoresis cassette made by combining plates made of a synthetic resin which has a cavity for forming a support, wherein the surface of the plate which contacts with the support is covered with a SiOx film, and the SiOx film has a contact angle to water of 30° or less.

2. An electrophoresis cassette according to claim 1, wherein a plastic film is provided between the surface of the support and the SiOx film.

3. An electrophoresis cassette according to claim 1, wherein an anchor treatment layer is provided between the surface of the support and the SiOx film.

4. An electrophoresis cassette according to claim 1, wherein a plastic film and an anchor treatment layer are provided between the surface of the support and the SiOx film, the plastic film is provided on the surface of the support, and the anchor treatment layer is provided between the plastic film and the SiOx film.

5. An electrophoresis cassette according to claim 3, wherein the anchor treatment layer and the SiOx film are successively formed.

6. An electrophoresis cassette according to claim 4, wherein the anchor treatment layer and the SiOx film are successively formed.

7. A production method for an electrophoresis cassette which is made by combining plates made of a synthetic resin in which an anchor treatment layer and a SiOx film are formed by a plasma chemical vapor deposition method directly on the plate or via a plastic film on the plate, wherein the formation of the anchor treatment layer and the SiOx film by a plasma chemical vapor deposition method is carried out successively using the same raw material gas.
